(19) United States
(12) Patent Application Publication
(10) Pub. No.: US 2026/0165070 A1
(43) Pub. Date: Jun. 11, 2026

(54) SUBSTRATE PROCESSING METHOD, SUBSTRATE PROCESSING APPARATUS, AND RECORDING MEDIUM

(71) Applicant: Tokyo Electron Limited, Tokyo (JP)

(72) Inventors: Yuhei MAEDA, Yokkaichi (JP); Akira NISHIYA, Koshi City (JP); Tsutomu TSUTSUI, Koshi City (JP); Tomoki OKAZAWA, Koshi City (JP); Hiromitsu HYODO, Koshi City (JP); Kosuke YOSHIHARA, Koshi City (JP); Shinichiro YAMANAKA, Koshi City (JP)

(73) Assignee: Tokyo Electron Limited, Tokyo (JP)

(21) Appl. No.: 19/180,433

(22) Filed: Apr. 16, 2025

(30) Foreign Application Priority Data
Apr. 17, 2024 (JP) 2024-066738

(51) Int. Cl. H10P 72/00

(52) U.S. Cl. CPC H10P 72/0428; H10P 72/0448; H10P 72/0604

(57) ABSTRACT

A substrate processing method includes supplying, while horizontally holding a stacked substrate formed by bonding a first substrate and a second substrate to each other in order for the first substrate to be located on the second substrate, a chemical liquid to a peripheral portion of the first substrate to move the chemical liquid from the peripheral portion of the first substrate into a gap between the first substrate and the second substrate; and hardening the chemical liquid moved into the gap.

### CROSS-REFERENCE TO RELATED APPLICATION

This application claims the benefit of Japanese Patent Application No. 2024-066738 filed on Apr. 17, 2024, the entire disclosures of which are incorporated herein by reference.

### TECHNICAL FIELD

The exemplary embodiments described herein pertain generally to a substrate processing method, a substrate processing apparatus, and a recording medium.

### BACKGROUND

Patent Document 1 discloses a substrate processing method, including: holding bonded substrates; preheating the bonded substrates; and filling a gap between the bonded substrates with a protective material along an edge of the substrates.

### PRIOR ART DOCUMENT

Patent Document 1: U.S. Pat. No. 9,508,659

### SUMMARY

In one exemplary embodiment, a substrate processing method includes supplying, while horizontally holding a stacked substrate formed by bonding a first substrate and a second substrate to each other in order for the first substrate to be located on the second substrate, a chemical liquid to a peripheral portion of the first substrate to move the chemical liquid from the peripheral portion of the first substrate into a gap between the first substrate and the second substrate; and hardening the chemical liquid moved into the gap.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a plan view schematically illustrating an outline of a configuration of a substate processing apparatus;

FIG. 2 is a side view illustrating an example of a liquid processing module;

FIG. 3 is a plan view schematically illustrating the liquid processing module;

FIG. 4A is a diagram for describing an operation of a control device that controls the liquid processing module to supply a first chemical liquid, and FIG. 4B is a diagram for describing an operation of the control device that controls the liquid processing module to supply a second chemical liquid;

FIG. 5A is a diagram for describing an example of filling a gap with the second chemical liquid by using the first chemical liquid as a primer, and FIG. 5B is a diagram for describing an example of filling an inside of the gap with the second chemical liquid;

FIG. 6 is a diagram illustrating an example of a second nozzle including a guide member;

FIG. 7 is a diagram illustrating another example of the second nozzle including the guide member;

FIG. 8 is a diagram illustrating an example of supplying the chemical liquid by the guide member;

FIG. 9 is a diagram illustrating an example of supplying the chemical liquid by an inert gas;

FIG. 10 is a diagram illustrating another example of supplying the chemical liquid by a nozzle;

FIG. 11 is a diagram illustrating an example of a hydrophilization processing on a stacked substrate;

FIG. 12 is a diagram illustrating an example of a cleaning processing on the stacked substrate;

FIG. 13 is a side view illustrating an example of a liquid processing module according to a modification example;

FIG. 14 is a side view illustrating another example of a liquid processing module according to a modification example;

FIG. 15 is a diagram illustrating an example of impregnating the stacked substrate in a liquid puddle;

FIG. 16 is a diagram illustrating an example of supplying the second chemical liquid by a plurality of jet dispensers;

FIG. 17A is a side view illustrating an example of a guide member that covers a peripheral portion of the stacked substrate, FIG. 17B is a plan view illustrating an example of the guide member that covers the peripheral portion of the stacked substrate, and FIG. 17C is a plan view illustrating another example of the guide member that covers the peripheral portion of the stacked substrate;

FIG. 18A is a diagram illustrating that the second chemical liquid is directly applied to the gap by a supply brush, and FIG. 18B is a diagram illustrating that the second chemical liquid is directly applied to the gap by a supply thread;

FIG. 19A is an example of a side view of a rotary holder according to a modification example, and FIG. 19B is an example of a side view of the rotary holder after vacuum-adsorption;

FIG. 20A is a plan view illustrating a state of the gap, FIG. 20B is a diagram schematically illustrating the degree of filling the gap with the second chemical liquid after supply of the second chemical liquid to the gap, and FIG. 20C is a diagram schematically illustrating the degree of filling the gap with the second chemical liquid after repetition of a first cycle;

FIG. 21A is a plan view illustrating a state of the gap, FIG. 21B is a diagram schematically illustrating the degree of filling the gap with the second chemical liquid after supply of the second chemical liquid to the gap, FIG. 21C is a diagram schematically illustrating the degree of filling the gap with the second chemical liquid after rotation of the stacked substrate at a second rotational speed, and FIG. 21D is a diagram schematically illustrating the degree of filling the gap with the second chemical liquid after repetition of the first cycle;

FIG. 22A is a diagram illustrating an example of measuring the peripheral portion by a detector, and FIG. 22B is a diagram illustrating an example of a projected image;

FIG. 23 is a diagram illustrating an example of a hardware configuration of the control device;

FIG. 24 is a flowchart illustrating an example of a substrate processing method that is performed by the control device to the liquid processing module according to the exemplary embodiment; and

FIG. 25 is a flowchart illustrating an example of a substrate processing method that is performed by the control device to the liquid processing module according to the modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a substrate processing apparatus according to exemplary embodiments will be described with reference to the drawings. Note that, in the description, the same reference signs are given to components having substantially the same functional configurations to omit duplicate explanations.

### Substrate Processing Apparatus

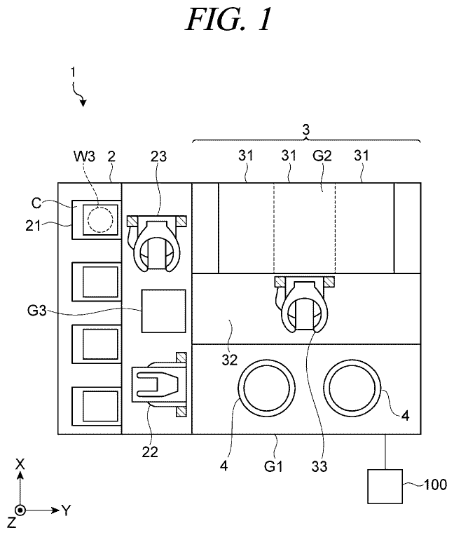

First, a configuration of a substrate processing apparatus according to the present exemplary embodiment will be described. FIG. 1 is a plan view schematically illustrating an outline of a configuration of a substate processing apparatus. A substate processing apparatus 1 is configured to fill a gap between a first substrate and a second substrate with a chemical liquid, with respect to a stacked substrate W3 in which the first substrate and the second substrate are bonded to each other.

As illustrated in FIG. 1, the substate processing apparatus 1 includes a cassette station 2 where a cassette C accommodating a plurality of stacked substrates W3 is carried in and carried out, and a processing station 3 having a plurality of various processing apparatuses to perform predetermined processing on the stacked substrate W3. The substate processing apparatus 1 has a configuration in which the cassette station 2 and the processing station 3 are integrally connected.

The cassette station 2 is equipped with a plurality of cassette placing tables 21 and substate transfer devices 22 and 23. In the cassette station 2, the stacked substrate W3 is transferred between the cassette C placed on the cassette placing table 21 and the processing station 3 by the substate transfer device 22 or the substate transfer device 23. Therefore, the substate transfer devices 22 and 23 may have drive mechanisms for respective directions such as longitudinal direction, widthwise direction, vertical direction, and rotational direction around a vertical axis (θ-direction) as needed, or may have a drive mechanism for all directions.

At least one of the substate transfer devices 22 and 23 is capable of delivering the stacked substrate W3 to and from the cassette C and is also capable of delivering the stacked substrate W3 to and from the processing station 3. Further, the delivery operation of the stacked substrate W3 to and from the processing station 3 involves, for example, delivering the stacked substrate W3 to and from a third block G3 having a delivery device accessible by a substate transfer device 33 in the processing station 3 to be described later. The third block G3 may be equipped with a plurality of delivery devices (not illustrated) arranged in the vertical direction.

The processing station 3 is equipped with a plurality of blocks, for example, a first block G1 and a second block G2. For example, a plurality of layers including the first block G1 and the second block G2 is stacked in the vertical direction. For example, the first block G1 is provided on the front side of the processing station 3 (on the negative side of the X-axis direction in FIG. 1), and the second block G2 is provided on the rear side of the processing station 3 (on the positive side of the X-axis direction in FIG. 1). Further, the third block G3 may be provided in the processing station 3.

In the first block G1, a plurality of liquid processing modules 4 is provided. The liquid processing module 4 is configured to supply a chemical liquid to the gap between the first substrate and the second substrate of the stacked substrate W3. In the second block G2, a plurality of hardening modules 31 (hardening devices) is provided. The hardening module 31 hardens the chemical liquid supplied to the gap between the first substrate and the second substrate by the liquid processing module 4. For example, if the chemical liquid is heat curable, the hardening module 31 may serve as a thermal treatment module to heat the stacked substrate W3. The thermal treatment module is equipped with, for example, a heating plate that supports the stacked substrate W3 and heats the stacked substrate W3 with a heater embedded in the heating plate. If the chemical liquid is photo curable, the hardening module 31 may serve as a light radiation module to radiate an energy beam, such as UV light, to the gap between the first substrate and the second substrate. If the chemical liquid is gas curable, the hardening module 31 may serve as a gas supply module to supply an inert gas to the gap between the first substrate and the second substrate.

A substrate transfer area 32 is formed between the first block G1 and the second block G2 when viewed from the top as illustrated in FIG. 1. For example, the substate transfer device 33 is located in the substrate transfer area 32. The substate transfer device 33 includes, for example, a transfer arm that is movable in the X-axis direction, the Y-axis direction, the θ-direction, and the vertical direction. The substate transfer device 33 may move inside the substrate transfer area 32 to transfer the stacked substrate W3 to predetermined devices in the first block G1, the second block G2, and the third block G3 around thereof.

The substate processing apparatus 1 may be further equipped with a polishing apparatus, a trimming apparatus, a patterning film forming apparatus, a developing apparatus, and an interface block. For example, after the chemical liquid in the gap inside the stacked substrate W3 is hardened, the polishing apparatus polishes surfaces of the first substrate and the second substrate. Thus, the polishing apparatus may adjust a thickness of the stacked substrate W3. For example, after polishing by the polishing apparatus, the trimming apparatus trims an outer edge of the stacked substrate W3 by polishing or the like. For example, the patterning film forming apparatus forms a film for patterning, such as a resist film, on the stacked substrate W3. In the developing apparatus, a portion of the film for patterning, which has been exposed by an exposure apparatus, is removed to form an uneven shape as a mask. The polishing apparatus, the trimming apparatus, the patterning film forming apparatus, and the developing apparatus may be provided in any one of the first block G1, the second block G2, and the third block G3. If the substate processing apparatus 1 is equipped with the patterning film forming apparatus and the developing apparatus, it may further include an interface station that delivers the stacked substrate W3 to and from the exposure apparatus.

The above-described substate processing apparatus 1 is equipped with a control device 100. The control device 100 is implemented by, for example, a computer, and includes a program storage (not shown). A program for controlling a processing of the stacked substrate W3 in the substate processing apparatus 1 is stored in the program storage. Further, the program storage stores therein a program for implementing a chemical liquid filling processing in the substate processing apparatus 1 by controlling the above-described various processing apparatuses and a driving system, such as the transfer devices. Furthermore, the programs may be recorded in a computer-readable recording medium H, and may be installed from this recording medium H to the control device 100.

The control device 100 controls the substrate transfer devices 22, 23 and 33 to take out the stacked substrate W3 from the cassette C placed on the cassette placing table 21 and carry the stacked substrate W3 into the liquid processing module 4. Then, the control device 100 controls the liquid processing module 4 to fill the gap between the first substrate and the second substrate with the chemical liquid, and controls the substrate transfer device 33 to carry the stacked substrate W3 out of the liquid processing module 4 and carry the stacked substrate W3 into the hardening module 31. Thereafter, the control device 100 controls the hardening module to harden the chemical liquid filled in the gap between the first substrate and the second substrate. Then, the control device 100 controls the substrate transfer devices 33, 22 and 23 to carry the stacked substrate W3 from the hardening module 31 and return the stacked substrate W3 to the inside of the cassette C.

Hereinafter, an example of a configuration of the liquid processing module 4 that easily fills the gap between the first substrate and the second substrate with the chemical liquid will be described.

### Liquid Processing Module

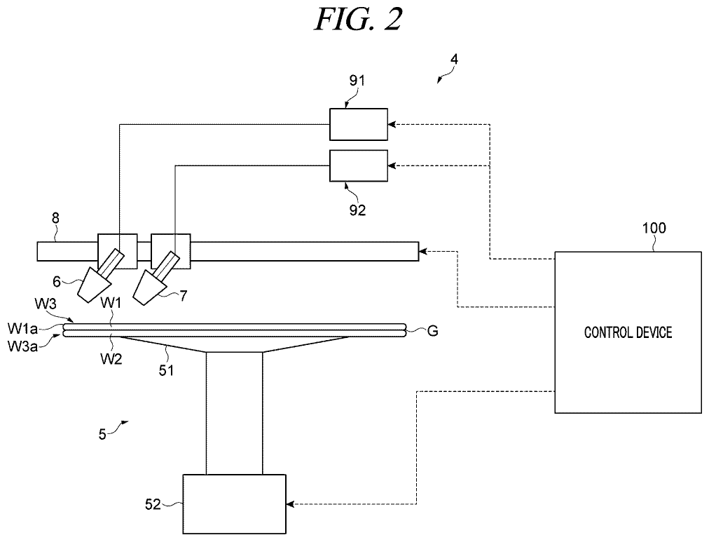

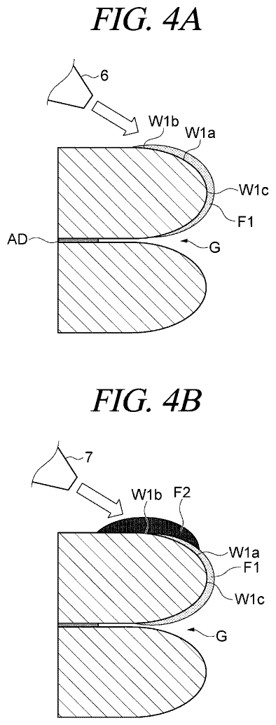

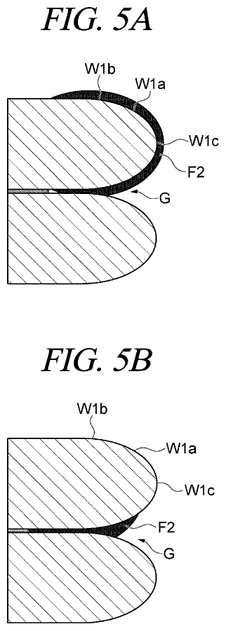

FIG. 2 is a side view illustrating an example of a liquid processing module. The liquid processing module 4 is equipped with a chemical liquid supply. The chemical liquid supply horizontally holds the stacked substrate W3 formed by bonding a first substrate W1 and a second substrate W2 to each other in order for the first substrate W1 to be located on the second substrate W2, supplies the chemical liquid to a peripheral portion W1a of the first substrate W1, and moves the chemical liquid from the peripheral portion W1a of the first substrate W1 into a gap G between the first substrate W1 and the second substrate W2. The chemical liquid supply is equipped with a first chemical liquid supply 91 and a second chemical liquid supply 92. In the liquid processing module 4, the chemical liquid does not need to reach the gap with high precision. Thus, it is possible to easily fill the gap G with the chemical liquid by suppressing the effects caused by bending of the stacked substrate W3. Further, the first substrate W1 and the second substrate W2 may be bonded to each other either without an adhesive through fusion bonding or anodic bonding, or with an adhesive (see an adhesive AD shown in FIG. 4A and FIG. 4B, and FIG. 5A and FIG. 5B).

The first chemical liquid supply 91 supplies a first chemical liquid to the gap G between the first substrate W1 and the second substrate W2 in a peripheral portion W3a of the stacked substrate W3 formed by bonding the first substrate W1 and the second substrate W2 to each other. The second chemical liquid supply 92 supplies a second chemical liquid to the gap G to substitute the first chemical liquid in the gap G with the second chemical liquid different from the first chemical liquid in the peripheral portion W3a. Since the first chemical liquid is supplied to the gap before the second chemical liquid to be hardened, it is possible to easily fill the gap G with the second chemical liquid by using the first chemical liquid in the gap G as a primer.

For example, the liquid processing module 4 is equipped with a rotary holder 5, a first nozzle 6, a second nozzle 7, a nozzle moving mechanism 8, the first chemical liquid supply 91, and the second chemical liquid supply 92.

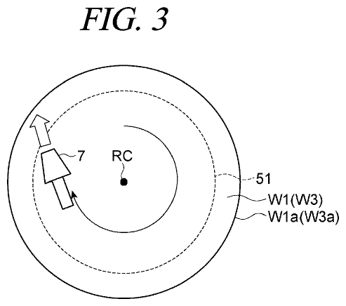

The rotary holder 5 holds and rotates the stacked substrate W3. The rotary holder 5 is equipped with, for example, a holder 51 and a rotation driving device 52. The holder 51 supports a central portion of the stacked substrate W3 disposed horizontally with the first substrate W1 facing upwards and holds the stacked substrate W3 by, for example, vacuum adsorption. The rotation driving device 52 is an actuator using, for example, an electric motor as a power source. FIG. 3 is a plan view schematically illustrating the liquid processing module. The rotation driving device 52 rotates the holder 51 around a vertical rotation center RC in response to an instruction from the control device 100. Thus, the stacked substrate W3 is rotated around the rotation center RC.

The first nozzle 6 discharges the first chemical liquid. The first chemical liquid supply 91 supplies the first chemical liquid to the first nozzle 6. The second nozzle 7 discharges the second chemical liquid. The second chemical liquid supply 92 supplies the second chemical liquid to the second nozzle 7. Each of the first chemical liquid supply 91 and the second chemical liquid supply 92 includes a supply line configured to supply the chemical liquid, a source of the chemical liquid, and a pump configured to feed the chemical liquid. For example, the first chemical liquid supply 91 drives the pump in response to an instruction from the control device 100 to supply the first chemical liquid to the first nozzle 6. Likewise, the second chemical liquid supply 92 drives the pump in response to an instruction from the control device 100 to supply the second chemical liquid to the second nozzle 7.

The nozzle moving mechanism 8 moves the first nozzle 6 and the second nozzle 7 to desired positions in response to, for example, an instruction from the control device 100. For example, the nozzle moving mechanism 8 places the first nozzle 6 at a position where the first chemical liquid can be supplied to the gap G. For example, the nozzle moving mechanism 8 places the first nozzle 6 to be directed from diagonally above toward an upper surface of the peripheral portion W1a of the first substrate W1 in a direction away from the rotation center RC of the stacked substrate W3. Thus, the first chemical liquid discharged from the first nozzle 6 is supplied to the upper surface of the peripheral portion W1a of the first substrate W1 from diagonally above in the direction away from the rotation center RC of the stacked substrate W3. The first chemical liquid supplied to the upper surface of the peripheral portion W1a is moved into the gap G along an outer peripheral surface of the first substrate W1.

For example, the nozzle moving mechanism 8 places the second nozzle 7 at a position where the second chemical liquid can be supplied to the gap G. For example, the nozzle moving mechanism 8 places the second nozzle 7 to be directed from diagonally above toward the upper surface of the peripheral portion W1a of the first substrate W1 in the direction away from the rotation center RC of the stacked substrate W3. Thus, the second chemical liquid discharged from the second nozzle 7 is supplied to the upper surface of the peripheral portion W1a of the first substrate W1 from diagonally above in the direction away from the rotation center RC of the stacked substrate W3. The second chemical liquid supplied to the upper surface of the peripheral portion W1a is moved into the gap G along the outer peripheral surface of the first substrate W1.

As illustrated in FIG. 3, the nozzle moving mechanism 8 may place, for example, the first nozzle 6 and the second nozzle 7 at an incline in a diametrical direction of the stacked substrate W3. In this case, the first nozzle 6 and the second nozzle 7 may be inclined toward a rotation direction of the peripheral portion W1a from the diametrical direction of the stacked substrate W3. The nozzle moving mechanism 8 may move the first nozzle 6 and the second nozzle 7 either separately or simultaneously. For example, the nozzle moving mechanism 8 moves the first nozzle 6 and the second nozzle 7 along a horizontal linear path using a power source such as an electric motor. In this case, the nozzle moving mechanism 8 may move the first nozzle 6 and the second nozzle 7 while fixing the orientations of the first nozzle 6 and the second nozzle 7.

The control device 100 causes the liquid processing module 4 to supply the chemical liquid to the peripheral portion W1a of the first substrate W1 while horizontally holding the stacked substrate W3 formed by bonding the first substrate W1 and the second substrate W2 to each other in order for the first substrate W1 to be located on the second substrate W2, and move the chemical liquid from the peripheral portion W1a of the first substrate W1 into the gap G between the first substrate W1 and the second substrate W2. The control device 100 may cause the liquid processing module 4 to perform supplying the first chemical liquid to the gap G between the first substrate W1 and the second substrate W2 in the peripheral portion W3a of the stacked substrate W3 formed by bonding the first substrate W1 and the second substrate W2 to each other, and to perform supplying the second chemical liquid to the gap G to substitute the first chemical liquid in the gap G with the second chemical liquid different from the first chemical liquid.

For example, the control device 100 controls the rotary holder 5 to horizontally hold and rotate the stacked substrate W3 in order for the first substrate W1 to be located on the second substrate W2. The control device 100 may control the nozzle moving mechanism 8 and the first chemical liquid supply 91 to supply the first chemical liquid from the first nozzle 6 to the gap G in a first region through which the peripheral portion W3a of the stacked substrate W3 passes by the rotation while rotating the stacked substrate W3. The first region includes a position where the peripheral portion W3a of the stacked substrate W3 passes through, as well as its surrounding area. Likewise, the control device 100 may control the nozzle moving mechanism 8 and the second chemical liquid supply 92 to supply the second chemical liquid from the second nozzle 7 to the gap G in the first region while rotating the stacked substrate W3. Thus, there is no need to move the first nozzle 6, which supplies the first chemical liquid, and the second nozzle 7, which supplies the second chemical liquid, along a circumferential direction of the stacked substrate W3. Therefore, it becomes easy to fill the gap G with the second chemical liquid.

The control device 100 may control the rotary holder 5 to rotate the stacked substrate W3 at a rotational speed that ensures a centrifugal force generated by the rotation does not hinder the movement of the second chemical liquid into the gap G during the supply of the first chemical liquid and the second chemical liquid. Thus, it is possible to facilitate the supply of the first chemical liquid and the second chemical liquid through the rotation of the stacked substrate W3 and ensure smooth movement of the first chemical liquid and the second chemical liquid into the gap G. For example, the control device 100 may set the rotational speed to 60 rpm or less or within a range of from 10 rpm to 60 rpm during the supply of the first chemical liquid and the second chemical liquid. The control device 100 may set different rotational speeds for the supply of the first chemical liquid and the supply of the second chemical liquid.

Hereinafter, an operation of supplying the chemical liquid by the liquid processing module 4 under the control of the control device 100 will be described in more detail with reference to FIG. 4A and FIG. 4B, and FIG. 5A and FIG. 5B. The control device 100 controls the liquid processing module 4 to supply a first chemical liquid F1 from the first nozzle 6 to the gap G. As illustrated in FIG. 4A, the control device 100 places the first nozzle 6 on the nozzle moving mechanism 8 to be directed from diagonally above toward the upper surface of the peripheral portion W1a of the first substrate W1 in the direction away from the rotation center RC of the stacked substrate W3. Then, the control device 100 supplies the first chemical liquid from the first chemical liquid supply 91 to the first nozzle 6. Thus, the first chemical liquid is supplied to the upper surface of the peripheral portion W1a of the first substrate W1. The first chemical liquid F1 supplied to an upper surface W1b moves from the upper surface W1b into the gap G along an outer peripheral surface W1c of the first substrate W1. As such, the first chemical liquid F1 can be supplied from the outer peripheral surface W1c without the effects caused by the bending of the stacked substrate W3.

Then, the control device 100 controls the liquid processing module 4 to supply a second chemical liquid F2 from the second nozzle 7 to the gap G. As illustrated in FIG. 4B, the control device 100 places the second nozzle 7 on the nozzle moving mechanism 8 to be directed from diagonally above toward the upper surface of the peripheral portion W1a of the first substrate W1 in the direction away from the rotation center RC of the stacked substrate W3. Then, the control device 100 supplies the second chemical liquid from the second chemical liquid supply 92 to the second nozzle 7. Thus, the second chemical liquid is supplied to the upper surface of the peripheral portion W1a of the first substrate W1. As illustrated in FIG. 5A, the second chemical liquid F2 supplied to the upper surface W1b moves from the upper surface W1b into the gap G along the outer peripheral surface W1c of the first substrate W1.

The first chemical liquid F1 filled in the gap G is substituted with the second chemical liquid F2 as illustrated in FIG. 5B. Since the first chemical liquid F1 is supplied to the gap G before the second chemical liquid F2 is supplied, it is possible to easily fill the gap G with the second chemical liquid F2 by using the first chemical liquid F1 in the gap G as the primer. The second chemical liquid F2 filled in the gap G is hardened by the hardening module 31 as described above.

A surface tension of the first chemical liquid F1 may be equal to or less than a surface tension of the second chemical liquid F2. In this case, the first chemical liquid F1 used as the primer can easily infiltrate deep into the gap G. Therefore, it is possible to easily fill the gap G with the second chemical liquid F2. The surface tension of the first chemical liquid F1 may be 30 mN/m or less. Herein, the term “surface tension” refers to, for example, the surface tension of a 0.1% solution in which the solute is 0.1 g and the solvent is 99.9 g. The surface tension of the first chemical liquid may be from 10 mN/m to 50 mN/m. In this case, the first chemical liquid F1 can more easily infiltrate deep into the gap G.

The first chemical liquid F1 may include, for example, a thinner. The first chemical liquid F1 may include at least one of polyethylene glycol monomethyl ether acetate and polyethylene glycol monomethyl ether. The first chemical liquid F1 may include only polyethylene glycol monomethyl ether acetate, only polyethylene glycol monomethyl ether, or both of them. Since the above-described liquids have a low surface tension, the first chemical liquid F1 can more easily infiltrate deep into the gap G.

A viscosity of the second chemical liquid F2 may be equal to or more than a viscosity of the first chemical liquid F1. The term “viscosity” refers to the ease of flow of a substance. Thus, the second chemical liquid F2 flows less easily than the first chemical liquid F1. In this case, the gap G is filled with the second chemical liquid F2 having a higher viscosity than the first chemical liquid F1 by using the first chemical liquid F1 as the primer, and, thus, it is possible to improve the strength of the peripheral portion W3a of the stacked substrate W3. The viscosity of the second chemical liquid F2 may be from 5 cP (centipoise) to 40 cP. Meanwhile, the viscosity of the first chemical liquid F1 may be from 1 cP to 5 cP.

The second chemical liquid F2 may be a heat curable liquid material. By hardening the second chemical liquid F2 through a heat treatment, the second chemical liquid F2 filled in the gap G can be easily hardened deep in the gap G. The second chemical liquid F2 may be, for example, spin-on glass (SOG). The second chemical liquid F2 may be an organic polymer solution containing glass components such as silica (SiO₂). The second chemical liquid F2 may also be a resist.

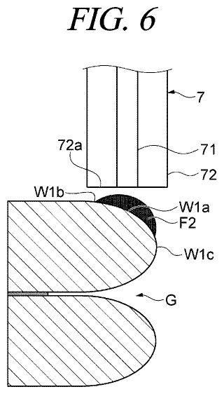

The liquid processing module 4 may be configured to facilitate the movement of the second chemical liquid F2 from the peripheral portion W1a of the first substrate W1 into the gap G by using a guide member. An example of the supply of the chemical liquid by using the guide member will be described with reference to FIG. 6 to FIG. 9.

As illustrated in FIG. 6, the liquid processing module 4 may further include a guide member 72. The guide member 72 faces the upper surface W1b while the second nozzle 7 supplies the second chemical liquid F2 to the peripheral portion W1a. Thus, the second chemical liquid F2 discharged from the second nozzle 7 is supplied between the upper surface W1b and the guide member 72. The guide member 72 may be integrally formed with the second nozzle 7. For example, the guide member 72 is provided to surround a chemical liquid path 71 of the second nozzle 7 and has a flat guide surface 72a that surrounds an opening of the chemical liquid path 71. The control device 100 may control the second nozzle 7 to supply the second chemical liquid F2 between the upper surface W1b and the guide member 72 in a state where the guide member 72 is positioned to face the upper surface W1b. For example, the control device 100 moves the second nozzle 7 to a position where the guide surface 72a of the guide member 72 faces the upper surface W1b, and starts the discharge of the chemical liquid from the chemical liquid path 71. In this case, the guide member 72 can suppress an upward scattering of the second chemical liquid F2 and thus facilitate the movement of the second chemical liquid F2 to the outer peripheral surface W1c.

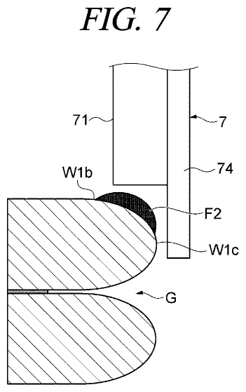

As illustrated in FIG. 7, the liquid processing module 4 may further include a guide member 74. The guide member 74 faces the outer peripheral surface W1c of the first substrate W1 while the second nozzle 7 supplies the second chemical liquid F2 to the peripheral portion W1a. Thus, the second chemical liquid F2 discharged from the second nozzle 7 is supplied between the upper surface W1b and the guide member 74. Thus, the second chemical liquid F2 discharged from the second nozzle 7 is supplied between the outer peripheral surface W1c and the guide member 74. The guide member 74 may be integrally formed with the second nozzle 7. The guide member 74 may be provided adjacent to a chemical liquid outlet path 73 in the direction away from the rotation center RC compared to the chemical liquid path 71. For example, a tip end of the guide member 74 may protrude downwards in the vertical direction compared to a cross section of the second nozzle 7, and may be located between the outer peripheral surface W1c and the gap G. The control device 100 may control the second nozzle 7 to supply the second chemical liquid F2 between the outer peripheral surface W1c and the guide member 74 in a state where the guide member 74 is positioned to face the outer peripheral surface W1c. For example, the control device 100 moves the second nozzle 7 to a position where the guide member 74 faces the outer peripheral surface W1c, and starts the discharge of the chemical liquid from the chemical liquid path 71. In this case, it is possible to facilitate the movement of the second chemical liquid F2 into the gap G by suppressing the movement of the second chemical liquid F2 in the direction away from the rotation center RC of the stacked substrate W3.

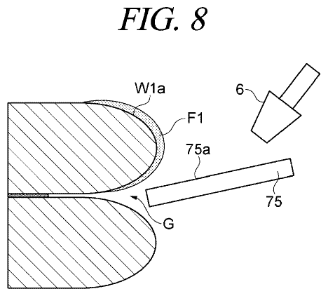

As illustrated in FIG. 8, the liquid processing module 4 may further include a guide member 75. The guide member 75 may be provided around the stacked substrate W3 and has a guide surface 75a that supports the first chemical liquid F1 from below. The guide surface 75a is inclined to become higher as it is farther from the stacked substrate W3. A tip end of the guide surface 75a is located between the first substrate W1 and the second substrate W2 at a position closest to the stacked substrate W3. The space between the first substrate W1 and the second substrate W2 refers to, for example, the space between the center of the thickness of the first substrate W1 and the center of the thickness of the second substrate W2. The guide member 75 facilitates the movement of the first chemical liquid F1 and the second chemical liquid F2 into the gap G along the inclined guide surface 75a. The control device 100 may control the nozzle moving mechanism 8 and the first chemical liquid supply 91 to supply the first chemical liquid F1 from the first nozzle 6 toward the guide surface 75a. Likewise, the control device 100 may control the nozzle moving mechanism 8 and the second chemical liquid supply 92 to supply the second chemical liquid F2 from the second nozzle 7 toward the guide surface 75a.

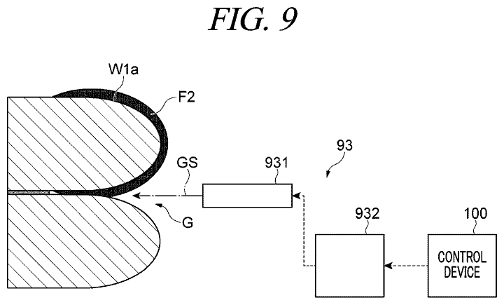

The liquid processing module 4 may further include a gas supply 93. As illustrated in FIG. 9, the gas supply 93 includes, for example, a gas nozzle 931 that discharges an inert gas toward the gap G from the outside around the stacked substrate W3, and a gas source 932 that supplies an inert gas GS to the gas nozzle 931. After the second chemical liquid F2 is supplied to the gap G, the control device 100 controls the gas supply 93 to further push the second chemical liquid F2 into the gap G. The inert gas GS is, for example, a nitrogen-containing gas. The inert gas is used to push the second chemical liquid F2 into the gap G. The control device 100 may control the gas supply 93 to further push the second chemical liquid F2 into the gap G by using the guide member 75. In this case, the control device 100 causes the gas nozzle 931 to discharge the inert gas GS to the guide surface 75a. Thus, the inert gas GS flows into the gap G along the guide surface 75a and pushes the second chemical liquid F2 into the gap G.

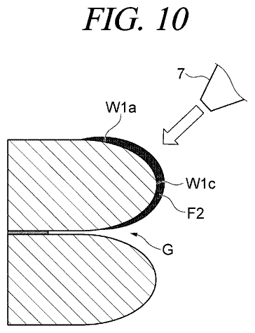

Herein, there has been described an example where the second nozzle 7 supplies the second chemical liquid F2 to the upper surface W1b of the first substrate W1, but the liquid processing module 4 may be configured to supply the second chemical liquid F2 toward the outer peripheral surface W1c of the first substrate W1. For example, as illustrated in FIG. 10, the nozzle moving mechanism 8 places the second nozzle 7 to be directed from diagonally above toward the outer peripheral surface W1c outside the peripheral portion W1a of the first substrate W1. Thus, the second chemical liquid F2 discharged from the second nozzle 7 is supplied to the outer peripheral surface W1c from diagonally above. The second chemical liquid F2 supplied to the outer peripheral surface W1c moves into the gap G. Since the second chemical liquid F2 is supplied from diagonally above, it is possible to suppress splashing back of the second chemical liquid F2 to the second nozzle 7 which is the source of the second chemical liquid F2.

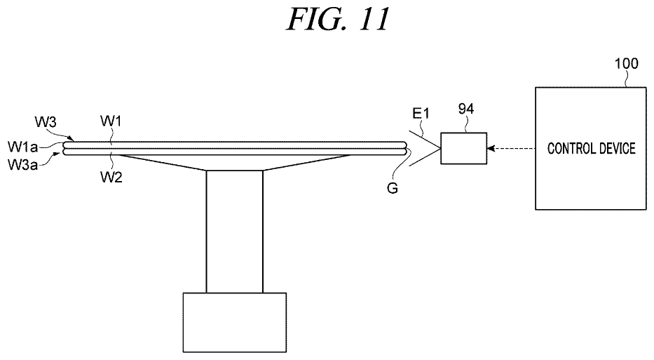

Before the first chemical liquid F1 is supplied, the liquid processing module 4 may be configured to perform a hydrophilization processing on the peripheral portion W3a of the stacked substrate W3. For example, as illustrated in FIG. 11, the liquid processing module 4 may further include a hydrophilization device 94. The hydrophilization device 94 may perform a hydrophilization processing by radiating an energy beam E1 to the peripheral portion W3a. The hydrophilization device 94 may be configured as a UV radiation device that performs a hydrophilization processing by radiating UV light to the peripheral portion W3a. The hydrophilization device 94 may be configured as a plasma radiation device that performs a hydrophilization processing by radiating a plasma beam to the peripheral portion W3a. Before the first chemical liquid F1 is supplied to the gap G, the control device 100 performs the hydrophilization processing. Since the hydrophilicity of the peripheral portion W3a of the stacked substrate W3 is improved, it is possible to more easily fill the gap G with the first chemical liquid F1 and the second chemical liquid F2.

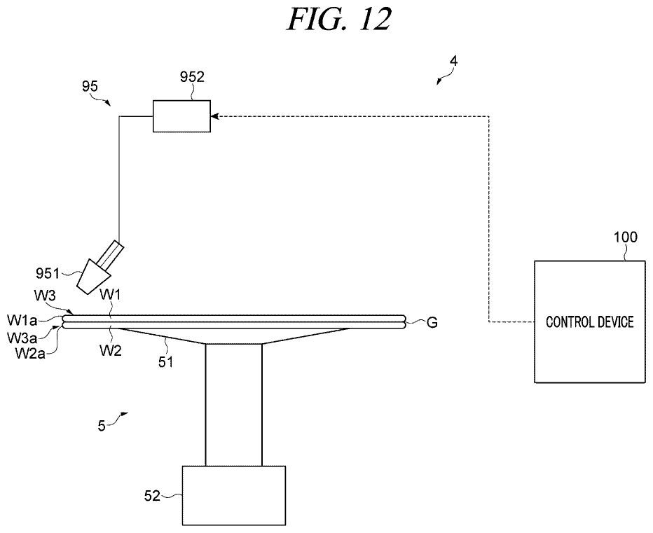

Some of the second chemical liquid F2 supplied to the peripheral portion W1a of the first substrate W1 does not move into the gap G, but may remain on the peripheral portion W1a. The liquid processing module 4 may be configured to supply a cleaning liquid to remove the second chemical liquid F2 remaining on the peripheral portion W1a of the first substrate W1. For example, as illustrated in FIG. 12, the liquid processing module 4 may further include a cleaning liquid supply 95. The cleaning liquid supply 95 includes, for example, a cleaning liquid nozzle 951 that is provided around the stacked substrate W3 and discharges a cleaning liquid, and a cleaning liquid source 952 that supplies the cleaning liquid to the cleaning liquid nozzle 951. For example, the control device 100 adjusts an angle of the cleaning liquid nozzle 951 in order for the cleaning liquid nozzle 951 to supply the cleaning liquid from diagonally above to the upper surface W1b in the direction away from the rotation center RC of the stacked substrate W3. After at least the second chemical liquid F2 is supplied to the gap G, the control device 100 controls the cleaning liquid supply 95 to start the supply of the cleaning liquid. The control device 100 may start the supply of the cleaning liquid during or after the supply of the second chemical liquid F2 to the gap G. For example, the cleaning liquid may be the same chemical liquid as the first chemical liquid F1. That is, the cleaning liquid may include at least one of polyethylene glycol monomethyl ether acetate and polyethylene glycol monomethyl ether. Due to the cleaning processing, it is not necessary to consider the second chemical liquid F2 remaining on the peripheral portion W1a of the first substrate W1. Therefore, it is possible to sufficiently supply the second chemical liquid F2 and easily fill the second chemical liquid F2 in the gap G.

When the cleaning liquid is supplied, the control device 100 causes the rotary holder 5 to horizontally hold and rotate the stacked substrate W3 in order for the first substrate W1 to be located on the second substrate W2. The control device 100 may set the rotational speed of the stacked substrate W3 when the cleaning liquid is supplied to the peripheral portion W1a of the first substrate W1 to be higher than the rotational speed of the stacked substrate W3 when the second chemical liquid F2 is supplied to the peripheral portion W1a and moved into the gap G. The rotary holder 5 may rotate the stacked substrate W3 at a rotational speed of 60 rpm or more. The rotary holder 5 may rotate the stacked substrate W3 at a rotational speed of, for example, from 500 rpm to 2000 rpm. In this case, it is possible to clean the peripheral portion W1a of the first substrate W1 while suppressing the flow of the cleaning liquid into the gap G.

Some of the second chemical liquid F2 supplied to the peripheral portion W1a of the first substrate W1 may be moved to a peripheral portion W2a of the second substrate W2 through the gap G. The liquid processing module 4 may be configured to supply a cleaning liquid to remove the second chemical liquid F2 remaining on the peripheral portion W2a of the second substrate W2. For example, the control device 100 adjusts an angle of the cleaning liquid nozzle 951 in order for the cleaning liquid nozzle 951 to supply the cleaning liquid from diagonally below to an upper surface of the second substrate W2 in the direction away from the rotation center RC of the stacked substrate W3. For example, after the second chemical liquid F2 is supplied to the gap G, the control device 100 starts the supply of the cleaning liquid. Even in this case, it is not necessary to consider the second chemical liquid F2 remaining on the peripheral portion W2a of the second substrate W2. Therefore, it is possible to sufficiently supply the second chemical liquid F2 and easily fill the second chemical liquid F2 in the gap G.

As described above, the control device 100 controls the liquid processing module 4 to supply the first chemical liquid F1 to the gap G before supplying the second chemical liquid to be hardened. Thus, it is possible to easily fill the gap G with the second chemical liquid by using the first chemical liquid in the gap G as the primer. This effect is not necessarily limited to the case where the second chemical liquid F2 is supplied to the gap G by moving the second chemical liquid F2 from the peripheral portion W1a of the first substrate W1 into the gap G between the first substrate W1 and the second substrate W2. The liquid processing module 4 may also be configured to directly supply the second chemical liquid F2 to the gap G. For example, the liquid processing module 4 may supply the second chemical liquid F2 from a nozzle (e.g., a head of a jet dispenser to be described later) so as to directly reach the gap G. In this case, the gap G can be more reliably filled with the second chemical liquid F2. Hereinafter, a liquid processing module that directly supplies the second chemical liquid F2 to the gap G will be described. Although the supply of the second chemical liquid F2 will be described as an example, the same may apply to the supply of the first chemical liquid F1.

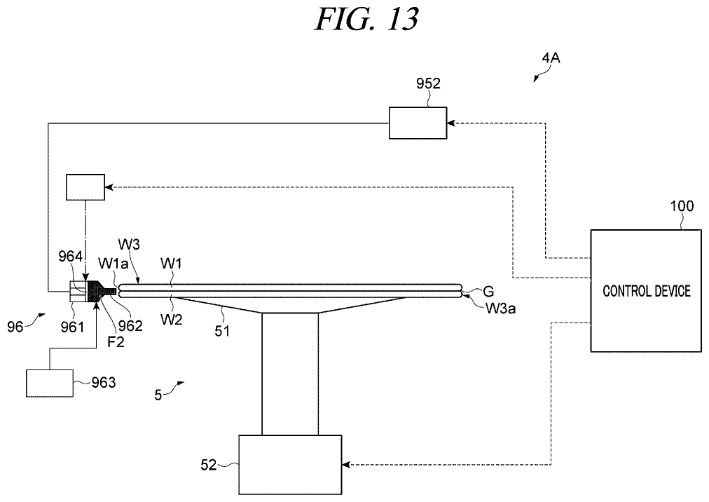

For example, a liquid processing module 4A illustrated in FIG. 13 is equipped with a jet dispenser 96 instead of the second nozzle 7. The jet dispenser 96 is equipped with a cylinder 961, a head 962, a reservoir tank 963, a plunger 964, and a plunger driver 965. The cylinder 961 is provided around the stacked substrate W3 and extends along a line directed toward the gap G. The cylinder 961 is, for example, a cylindrical container and accommodates therein the second chemical liquid F2. The head 962 is provided at an end portion of the cylinder 961 and directed toward the stacked substrate W3. The head 962 discharges the second chemical liquid F2 toward the gap G. The reservoir tank 963 accommodates therein the second chemical liquid F2 and supplies the second chemical liquid F2 to the cylinder 961. The reservoir tank 963 supplies the second chemical liquid F2 from a liquid supply port provided in the cylinder 961 via, for example, a liquid supply tube. The plunger 964 reciprocates inside the cylinder 961. As the plunger 964 moves in a direction away from the head 962, a pressure inside the cylinder 961 decreases, and, thus, the chemical liquid is supplied from the reservoir tank 963 into the cylinder 961. As the plunger 964 moves toward the head 962, the pressure inside the cylinder 961 increases, and, thus, the second chemical liquid F2 is discharged from the head 962.

When the reciprocation motion of the plunger 964 is made by the plunger driver 965, the control device 100 may repeat the supply of the second chemical liquid F2 to the gap G and the supplement of the second chemical liquid F2 from the reservoir tank 963. In this case, the second chemical liquid F2 is intermittently supplied at a high speed, and, thus, it is possible to more reliably fill the gap G with the second chemical liquid F2. For example, the control device 100 may output a driving signal having a predetermined frequency to the plunger driver 965, and the plunger driver 965 may make the reciprocation motion of the plunger 964 in response to the driving signal.

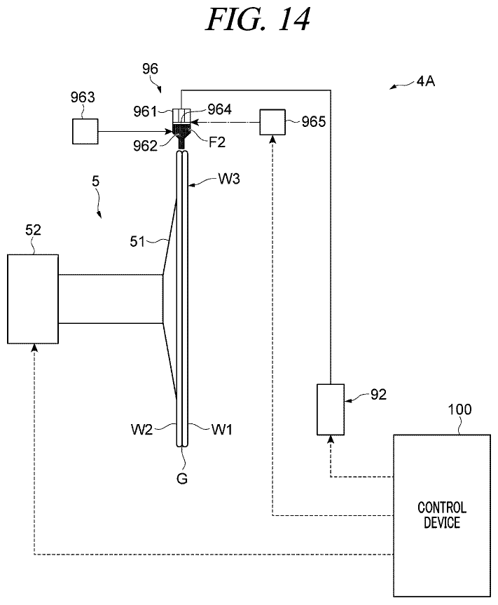

FIG. 14 is a side view illustrating another example of the liquid processing module according to the modification example. In the example of FIG. 14, the rotary holder 5 rotates the stacked substrate W3 around a horizontal rotation shaft while vertically keeping the stacked substrate W3 held on the holder 51. In this case, the jet dispenser 96 is disposed vertically above the stacked substrate W3 and discharges the second chemical liquid F2 toward the gap G located vertically lower than the jet dispenser 96.

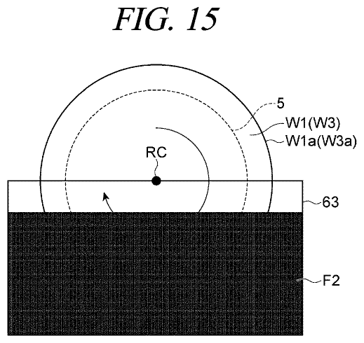

As illustrated in FIG. 15, the liquid processing module 4A may be configured to supply the second chemical liquid F2 to the gap G by immersing a part of the stacked substrate W3 in a liquid puddle. For example, the liquid processing module 4A may be further equipped with, instead of the second nozzle 7, a reservoir 63 that forms the liquid puddle. The reservoir 63 has an open top to store and preserve the second chemical liquid F2 supplied from the second chemical liquid supply 92. The stacked substrate W3 is located in order for a lower part of the peripheral portion W3a to be immersed in the liquid puddle of the second chemical liquid F2 in the reservoir 63 and rotated around the horizontal rotation shaft. Thus, the entire circumference of the peripheral portion W3a is immersed in the liquid puddle. The second chemical liquid F2 in the liquid puddle infiltrates into the gap G by capillarity. While the peripheral portion W3a is immersed in the liquid puddle, a greater amount of the second chemical liquid F2 is supplied to the peripheral portion W3a. Thus, it is possible to more thoroughly fill the gap G with the second chemical liquid F2.

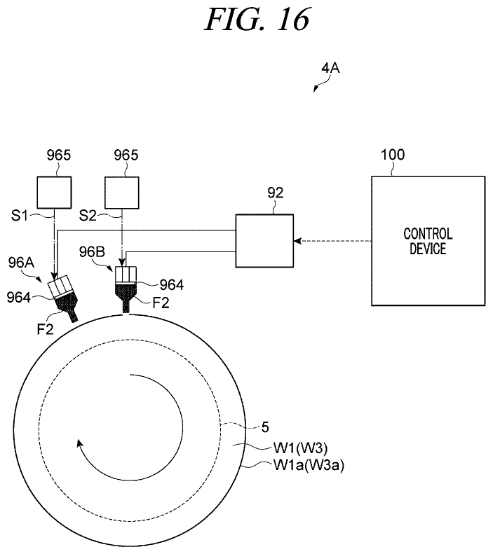

The liquid processing module 4A may be configured to perform a first set of supply operations for supplying the second chemical liquid F2 across the entire circumference at a predetermined cycle and a second set of supply operations for supplying the second chemical liquid F2 across the entire circumference at the same predetermined cycle, but at a different phase from that of the first set of supply operations. The term “different phase” means that positions where the second chemical liquid F2 is supplied to the peripheral portion W3a differ in the circumferential direction between the first and second sets of supply operations. The liquid processing module 4A may also be configured to perform the first and second sets of supply operations at two separate positions, respectively, in the circumferential direction. For example, as illustrated in FIG. 16, the liquid processing module 4A may include two jet dispensers 96A and 96B arranged in the circumferential direction. Each of the jet dispensers 96A and 96B has the same configuration as the jet dispenser 96. By at least partially overlapping a period of performing the first set of supply operations with a period of performing the second set of supply operations, a period of supplying the second chemical liquid F2 to the gap G can be shortened.

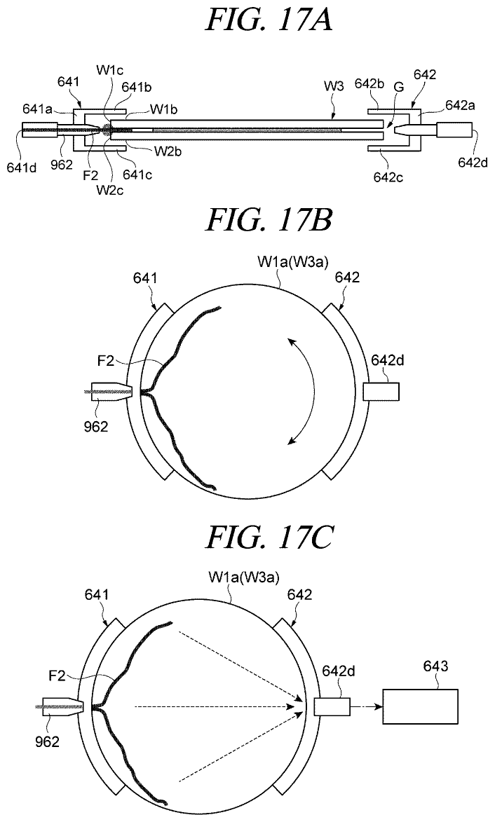

The liquid processing module 4A may be configured to supply the second chemical liquid F2 while covering a supply place of the second chemical liquid F2 with a guide member. For example, as illustrated in FIG. 17A, the liquid processing module 4A is equipped with a guide member 641 instead of the jet dispenser 96. In the example of FIG. 17A to FIG. 17C, the stacked substrate W3 is horizontally placed on the rotary holder 5. The guide member 641 is configured to cover outer peripheral surfaces W1c and W2c, the upper surface W1b of the first substrate W1, and an upper surface W2b of the second substrate W2 in a part of the peripheral portion W3a of the stacked substrate W3. For example, the guide member 641 includes a portion 641a that covers the outer peripheral surfaces W1c and W2c, a portion 641b that covers the upper surface W1b of the first substrate W1, and a portion 641c that covers the upper surface W2b of the second substrate W2. The second chemical liquid supply 92 supplies the second chemical liquid F2 into the guide member 641. For example, the guide member 641 includes a chemical liquid supply port 641d in the portion 641a. For example, the supply port 641d is provided at the center of the portion 641a in the circumferential direction of the stacked substrate W3. The second chemical liquid supply 92 supplies the second chemical liquid F2 from the supply port 641d into the guide member 641. The second chemical liquid F2 supplied into the guide member 641 is held on the portions 641a, 641b and 641c by, for example, a surface tension, and the peripheral portion W3a comes into contact with the second chemical liquid F2 held on the peripheral portion W3a. Thus, the second chemical liquid F2 is supplied to the gap G.

The liquid processing module 4A may be further equipped with a guide member 642 and a suction device 643. The guide member 642 is disposed at a position opposite to the guide member 641 in the circumferential direction of the stacked substrate W3. Like the guide member 641, the guide member 642 covers the outer peripheral surfaces W1c and W2c, the upper surface W1b of the first substrate W1, and the upper surface W2b of the second substrate W2 in a part of the peripheral portion W3a. For example, the guide member 642 includes a portion 642a that covers the outer peripheral surfaces W1c and W2c, a portion 642b that covers the upper surface W1b of the first substrate W1, and a portion 642c that covers the upper surface W2b of the second substrate W2, and also includes a suction port 642d in the portion 642a. For example, as illustrated in FIG. 17B, the suction port 642d is provided at the center of the portion 642a in the circumferential direction of the stacked substrate W3. The suction device 643 sucks a gas in the guide member 642 from the suction port 642d. In the peripheral portion W3a, an airstream is generated from the supply port 641d toward the suction port 642d in the circumferential direction by the guide member 641, the guide member 642, and the suction device 643. As illustrated in FIG. 17C, the second chemical liquid F2 supplied to the supply port 641d is spread in the circumferential direction by the generated airstream and thus supplied to the gap G over a wider range.

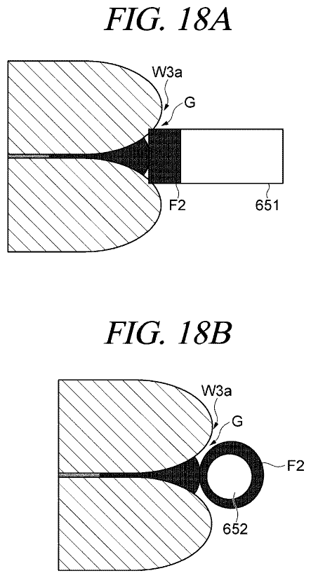

In the liquid processing module 4A, the second chemical liquid F2 may be supplied by a supply member configured to directly apply the second chemical liquid F2 to the gap G. As illustrated in FIG. 18A, the liquid processing module 4A may further include a supply member 651. In the example of FIG. 18A, the supply member 651 is a brush. The supply member 651 is provided near the gap G with the second chemical liquid F2 coated on the brush of the supply member 651. In this state, the control device 100 controls the rotary holder 5 to horizontally hold and rotate the stacked substrate W3. Thus, the second chemical liquid F2 coated on the brush of the supply member 651 is supplied to the gap G.

As illustrated in FIG. 18B, a supply member 652 may be a filament-shaped member. The supply member 652 is provided near the gap G with the second chemical liquid F2 coated on a surface of the supply member 652. In this state, the control device 100 controls the rotary holder 5 to horizontally hold and rotate the stacked substrate W3. Thus, the second chemical liquid F2 coated on the surface of the supply member 652 is supplied to the gap G.

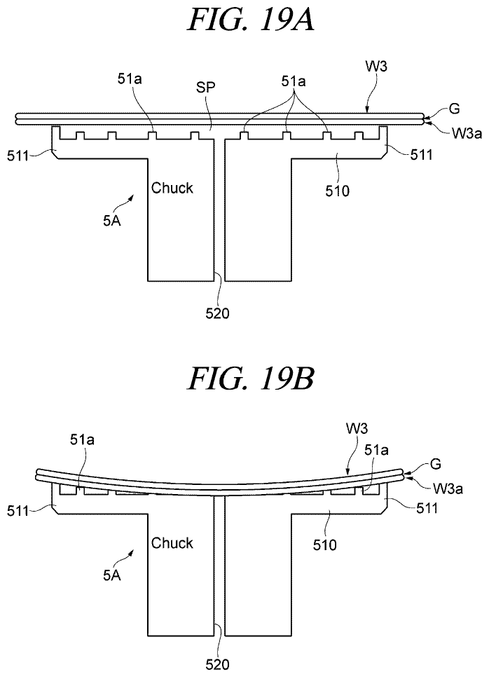

The liquid processing module 4A may be configured to perform a processing while the stacked substrate W3, which is horizontally placed, is curved such that its periphery is higher than its center. For example, as illustrated in FIG. 19A and FIG. 19B, the liquid processing module 4 or 4A may be equipped with a rotary holder 5A instead of the rotary holder 5. The rotary holder 5A includes a support plate 510 and a suction port 520. The support plate 510 extends horizontally over the entire circumference from the rotation center and supports the stacked substrate W3 from below. The support plate 510 includes a support wall 511. The support wall 511 is formed along the entire circumference of a periphery of an upper surface 51a of the support plate 510 and protrudes upwards from the upper surface 51a. The stacked substrate W3 is supported by the support wall 511. Since the support wall 511 supports the stacked substrate W3, a space SP is formed between the upper surface 51a and the stacked substrate W3. The suction port 520 is an opening formed at the center of the upper surface 51a. When the upper surface 51a adsorbs the stacked substrate W3, a gas in the space SP is sucked from the suction port 520. Thus, a portion of the stacked substrate W3 located inside the support wall 511 is drawn toward the upper surface 51a. Thus, the stacked substrate W3 is curved such that its periphery is higher than its center. As described above, the rotary holder 5A rotates the stacked substrate W3 being curved, and the jet dispenser 96 supplies the second chemical liquid F2 to the gap G. The jet dispenser 96 may be inclined diagonally downwards in accordance with the curve of the stacked substrate W3.

The control device 100 may control the liquid processing module 4 or 4A to repeat a plurality of times the supply of the second chemical liquid F2 to the gap G and then control the hardening module 31 to harden the second chemical liquid F2. For example, the control device 100 may control the liquid processing module 4 or 4A to repeat a plurality of times the supply of the second chemical liquid F2 to the peripheral portion W1a of the first substrate W1 and the movement of the second chemical liquid F2 from the peripheral portion W1a into the gap G. Then, the control device 100 may control the hardening module 31 to harden the second chemical liquid F2. When the supply of the second chemical liquid F2 to the gap G is set to a first cycle, there may be places where the second chemical liquid F2 is not fully filled within the first cycle. However, through repetition of the first cycle, the second chemical liquid F2 can be filled. Therefore, the second chemical liquid F2 can be more adequately filled.

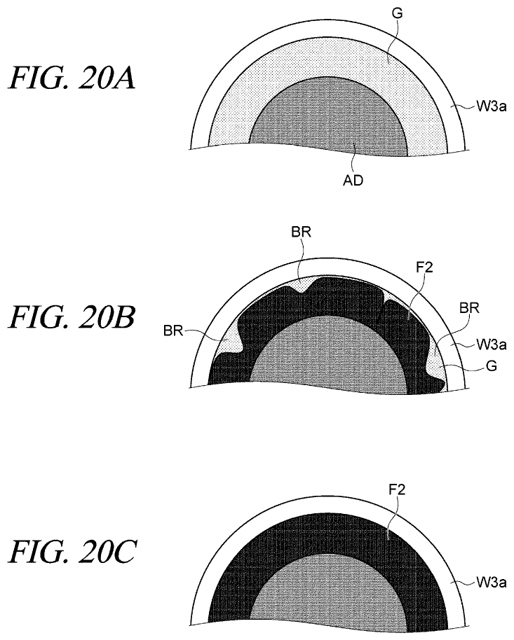

FIG. 20A to FIG. 20C are plan views illustrating a state of the gap G. In the gap G formed in the peripheral portion W3a as illustrated in FIG. 20A, the second chemical liquid F2 is filled as illustrated in FIG. 20B after the first cycle is completed. With only the first cycle, unfilled places BR remain in the gap G. However, as illustrated in FIG. 20C, through repetition of the first cycle, the second chemical liquid F2 is also filled in the unfilled places BR.

The control device 100 may control the liquid processing module 4 or 4A to repeat a plurality of times the supply of the first chemical liquid F1 to the gap G and the supply of the second chemical liquid F2 to the gap G and then control the hardening module 31 to harden the second chemical liquid F2. Therefore, by also repeatedly supplying the first chemical liquid F1 to the gap G, the second chemical liquid F2 can be more adequately filled.

After performing the supply of the second chemical liquid F2 and before performing the next supply of the second chemical liquid F2, the control device 100 may control the liquid processing module 4 or 4A to temporarily increase the rotational speed of the stacked substrate W3 for the supply of the second chemical liquid F2. For example, the control device 100 may control the rotary holder 5 to rotate the stacked substrate W3 at a second rotational speed which is higher than the rotational speed of the stacked substrate W3 for the supply of the second chemical liquid F2.

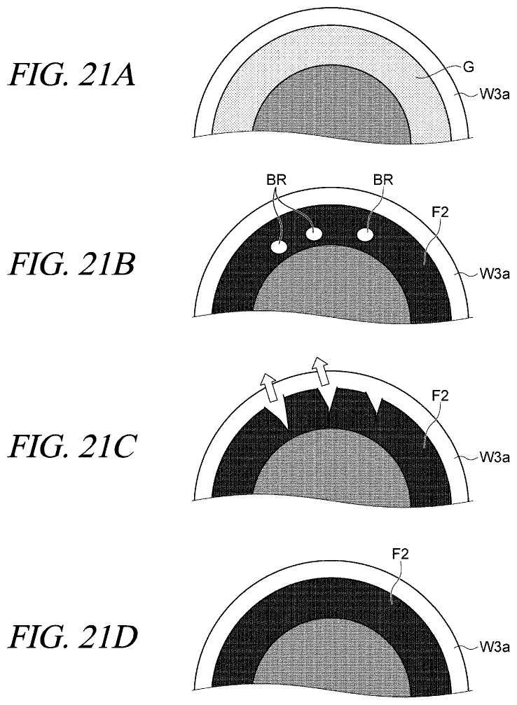

FIG. 21A to FIG. 21D are plan views illustrating a state of the gap G. In the gap G formed in the peripheral portion W3a of the stacked substrate W3 as illustrated in FIG. 21A, the second chemical liquid F2 is filled as illustrated in FIG. 20B after the first cycle is completed. After the first cycle, the unfilled places BR may remain trapped in the form of air bubbles inside the gap G. In this case, by temporarily increasing the rotational speed of the stacked substrate W3, the unfilled places BR are elongated outwards due to the centrifugal force of the rotation and opened to the outside (outside the peripheral portion W3a of the stacked substrate W3) as illustrated in FIG. 21C. Therefore, in the next cycle, the second chemical liquid F2 can be easily filled into the unfilled places BR as illustrated in FIG. 21D.

When the liquid processing module 4 or 4A repeats the supply of the first chemical liquid F1 and the supply of the second chemical liquid F2, the control device 100 may control the liquid processing module 4 or 4A to temporarily increase the rotational speed for the supply of the second chemical liquid F2 after performing the supply of the second chemical liquid F2 and before performing the supply of the first chemical liquid F1.

After the control device 100 controls the liquid processing module 4 or 4A to repeat a plurality of times the supply of the second chemical liquid F2 to the gap G and the temporary increase of the rotational speed of the stacked substrate W3, the control device 100 may control the hardening module 31 to harden the second chemical liquid F2. For example, the control device 100 may control the liquid processing module 4 or 4A to repeat a plurality of times the supply of the first chemical liquid F1 to the gap G, the supply of the second chemical liquid F2 to the gap G, and the rotation of the stacked substrate W3 at the second rotational speed, and then control the hardening module 31 to harden the second chemical liquid F2. Since the temporary increase of the rotational speed of the stacked substrate W3 is repeated a plurality of times, the unfilled places BR can be more reliably filled with the second chemical liquid F2.

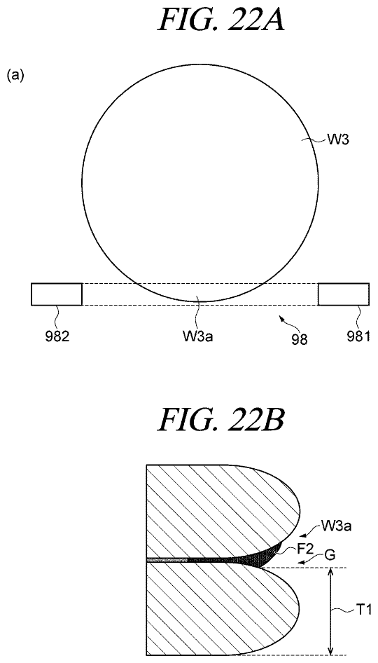

The control device 100 may be configured to control the liquid processing module 4 or 4A based on a state of the second chemical liquid F2 in the gap G. For example, the liquid processing module 4 or 4A may be further equipped with a detector 98 configured to detect the shape and the size of the peripheral portion W3a of the stacked substrate W3. FIG. 22A and FIG. 22B are diagrams illustrating an example of measuring the peripheral portion by the detector. The detector 98 may be, for example, a projected image measurement device. As illustrated in FIG. 22A, the detector 98 may include a light-emitting device 981 and a light-receiving device 982. The light-emitting device 981 and the light-receiving device 982 are disposed with a part of the peripheral portion W3a interposed therebetween along a direction of the stacked substrate W3. Light emitted from the light-emitting device 981 passes through the peripheral portion W3a to enter the light-receiving device 982. The light-receiving device 982 includes, for example, a screen. A shadow of the peripheral portion W3a is projected on the screen of the light-receiving device 982. The light-receiving device 982 generates data of the projected image. The control device 100 may detect a state (height, shape and size) of the peripheral portion W3a based on the data generated by the light-receiving device 982. Examples of the state of the peripheral portion W3a may include the height and the shape of the peripheral portion W3a of the stacked substrate W3, the thickness of the peripheral portion W1a of the first substrate W1, the thickness of the peripheral portion W2a of the second substrate W2, the thickness of the gap G, the inclination angle of the peripheral portion W1a, and the inclination angle of the peripheral portion W2a.

FIG. 22B is a diagram illustrating an example of the projected image. For example, the control device 100 may detect, from the projected image, a position (e.g., height) of the gap G in the vertical direction. The control device 100 may control a supply position of the second chemical liquid F2, i.e., a position where the second chemical liquid F2 is supplied from the head 962 to the gap G, based on the detection result of the position of the gap G. For example, the control device 100 may control the nozzle moving mechanism 8 to align the position of the gap G with the position of the head 962. In this case, the supply position of the second chemical liquid F2 is dynamically adapted to the detection result of the position of the gap G, and, thus, the second chemical liquid F2 can be more reliably supplied to the gap G.

The control device 100 may adjust a supply parameter of the second chemical liquid F2 based on the detection result of the state of the second chemical liquid F2. The supply parameter may include the number of repetitions of the above-described cycle, a period of supply time of the first chemical liquid F1 or the second chemical liquid F2, or the supply amount of the second chemical liquid F2 (e.g., the supply amount per unit time or the length of supply time). Since the supply parameter of the second chemical liquid F2 is dynamically adapted to the detection result of the state of the second chemical liquid F2, the second chemical liquid F2 can be more reliably supplied to the gap G.

For example, the control device 100 may detect the degree of filling the gap G with the second chemical liquid F2 based on the state of the second chemical liquid F2 and adjust the supply amount of the second chemical liquid F2 based on the degree of filling. For example, the control device 100 may calculate the ratio of the area occupied by the second chemical liquid F2 to the area of the gap G in the image as the degree of filling.

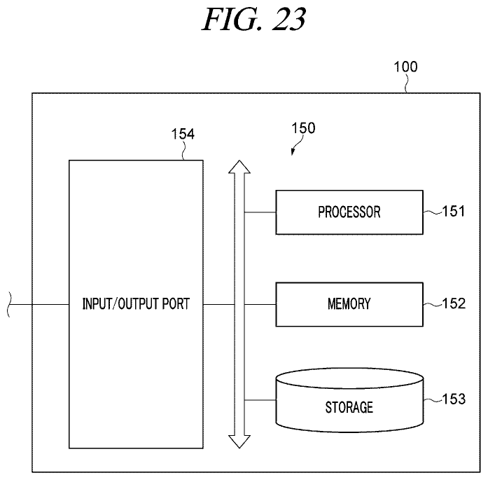

The program storage of the control device 100 may store therein a program for controlling processing of the stacked substrate W3 in the liquid processing module 4 or 4A and a heat treatment apparatus. The control device 100 is composed of one or more control computers. FIG. 23 is a diagram illustrating an example of a hardware configuration of the control device. For example, the control device 100 is equipped with a circuit 150 shown in FIG. 23. The circuit 150 is equipped with one or more processors 151, a memory 152, a storage 153, and an input/output port 154. The storage 153 has a computer-readable recording medium such as a hard disk. The recording medium stores therein a program for allowing the control device 100 to implement the substrate processing method by using the liquid processing module 4 or 4A and the heat treatment apparatus. The recording medium may be an extractable medium such as a non-volatile semiconductor memory, a magnetic disk or an optical disk. The recording medium may also be a computer-readable recording medium. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The memory 152 temporarily stores therein the program loaded from the recording medium of the storage 153 and an operation result by the processor 151. The processor 151 constitutes the above-described individual functional modules by executing the program in cooperation with the memory 152. The input/output port 154 performs input/output of electrical signals between the parts of the processing station 3 in response to instructions from the processor 151. The control device 100 may be composed of a plurality of control computers. The hardware configuration of the control device 100 is not necessarily limited to constituting the individual functional modules by the program. For example, the individual functional modules of the control device 100 may be composed of exclusive logical circuits or an ASIC (Application Specific Integrated Circuit) in which these logical circuits are integrated.

### Substrate Processing Sequence

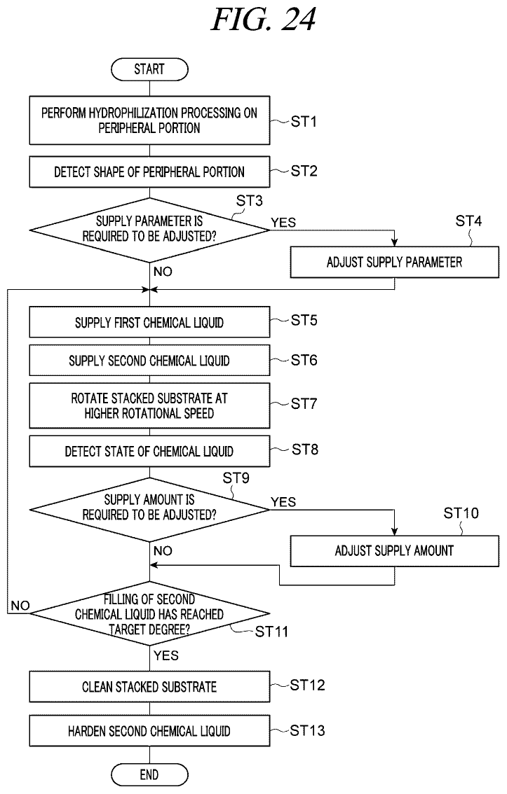

A substrate processing sequence performed by the control device 100 will be described as an example of a substrate processing method. FIG. 24 is a flowchart illustrating an example of the substrate processing procedure that is performed by the control device. The flowchart shown in FIG. 24 is an example where the control device 100 controls the liquid processing module 4 to supply the second chemical liquid F2 to the gap G by moving the second chemical liquid F2 into the gap G. As illustrated in FIG. 24, the control device 100 performs processes ST1 to ST13 in sequence. In the process ST1, the hydrophilization device 94 performs the hydrophilization processing on the peripheral portion W3a of the stacked substrate W3 before the supply of the first chemical liquid F1. In the process ST2, the control device 100 detects the shape of the peripheral portion W3a of the stacked substrate W3 from the image input by the detector 98. In the process ST3, the control device 100 determines whether the supply parameter of at least one of the first chemical liquid F1 and the second chemical liquid F2 is required to be adjusted based on the detection result of the shape of the peripheral portion W3a. When the supply parameter is required to be adjusted (process ST3: YES), the control device 100 adjusts the supply parameter in a process ST4. For example, when the thickness of the gap G is greater than the reference thickness, the control device 100 sets the supply amounts of the first chemical liquid F1 and the second chemical liquid F2 to be higher.

Then, the control device 100 performs the process ST5. When the supply parameter is not required to be adjusted (process ST3: NO), the control device 100 performs the process ST5 without performing the process ST4. In the process ST5, the control device 100 controls the liquid processing module 4 to supply the first chemical liquid F1 to the first substrate W1 and move the first chemical liquid F1 into the gap G. Thereafter, in the process ST6, the control device 100 controls the liquid processing module 4 to supply the second chemical liquid F2 to the first substrate W1 and move the second chemical liquid F2 into the gap G to substitute the first chemical liquid F1 in the gap G with the second chemical liquid F2. Then, in the process ST7, the control device 100 temporarily increases the rotational speed of the stacked substrate W3. For example, the control device 100 increases the rotational speed of the stacked substrate W3 to the second rotational speed and then returns it to the original rotational speed. Thereafter, in the process ST8, the control device 100 detects the state of the second chemical liquid F2 supplied to the gap G from the image input by the detector 98. In the process ST9, the control device 100 determines whether the supply amount of at least one of the first chemical liquid F1 and the second chemical liquid F2 is required to be adjusted based on the detection result of the state of the second chemical liquid F2. When the supply amount is required to be adjusted (process ST9: YES), the control device 100 adjusts the supply amount in the process ST10. Then, the control device 100 performs the process ST11. When it is determined that the supply amount is not required to be adjusted in the process ST9, the control device 100 performs the process ST11 without performing the process ST10. In the process ST11, the control device 100 determines whether the filling of the second chemical liquid F2 in the gap G has reached the target degree based on the detection result of the state of the second chemical liquid F2. When it is determined that the second chemical liquid F2 is not sufficiently filled in the gap G (process ST11: NO), the control device 100 returns to the process ST5. Accordingly, the processes ST5 to ST9 are repeated.

When it is determined that the filling of the second chemical liquid F2 in the gap G has reached the target degree (process ST11: YES), the control device 100 controls the liquid processing module 4 to supply the cleaning liquid to the peripheral portion W3a of the stacked substrate W3 from the cleaning liquid supply 95 in the process ST12. Then, in the process ST13, the control device 100 controls the hardening module 31 to harden the second chemical liquid F2. Thus, the substrate processing sequence is ended.

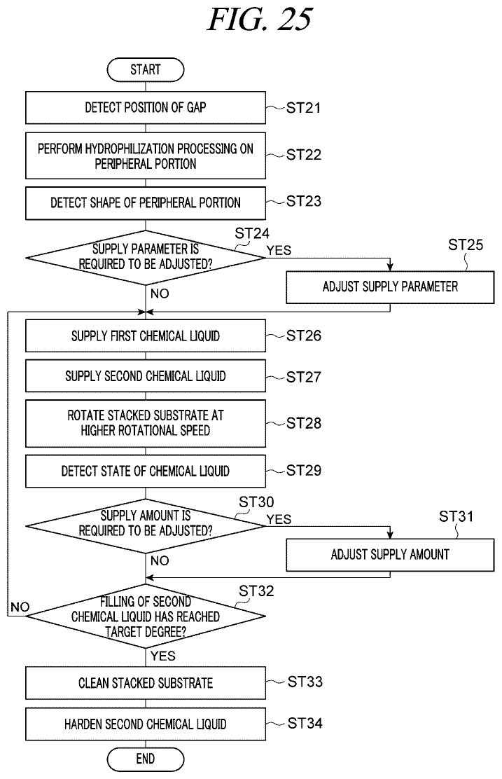

FIG. 25 is a flowchart illustrating another example of the substrate processing procedure that is performed by the control device. The flowchart shown in FIG. 25 is an example where the control device 100 controls the liquid processing module 4A to directly supply the second chemical liquid F2 to the gap G. First, the control device 100 performs a process ST21. In the process ST21, the control device 100 detects the position of the gap G from the image input by the detector 98. The control device 100 may sequentially detect the positions of the gap G while causing the rotary holder 5 to rotate the stacked substrate W3 and may generate the profile representing the relationship between the rotational angle of the stacked substrate W3 and the position of the gap G.

Then, the control device 100 performs the processes ST22 to ST34 corresponding to the processes ST1 to ST13, respectively. In the process S27 corresponding to the process ST6, the liquid processing module 4A supplies the second chemical liquid F2 to the gap G. In that period, the control device 100 may control the nozzle moving mechanism 8 to adjust the position of the jet dispenser 96 depending on the rotational angle of the stacked substrate W3 based on the above-described profile.

While the exemplary embodiments and modification examples have been described, these exemplary embodiments have been presented by way of example only, and are not intended to limit the scope of the disclosures. The exemplary embodiments described herein may be embodied in a variety of other forms.

The above-described exemplary embodiments and modification examples may be appropriately combined. For example, the guide members 72 and 74 described above with reference to FIG. 6 and FIG. 7 may be provided in the jet dispenser 96 of the liquid processing module 4A. For example, the rotary holder 5A described above with reference to FIG. 19A and FIG. 19B may be applied to the liquid processing module 4. In the substrate processing sequence performed to the liquid processing module 4 described above with reference to FIG. 24, the processes ST1 to ST4, ST9 and ST10 may not be performed. In the substrate processing sequence performed to the liquid processing module 4A described above with reference to FIG. 25, the processes ST21 to ST25, ST30 and ST31 may not be performed.

The above-described exemplary embodiments and modification examples include the following configurations.
[1] A substrate processing method including: supplying, while horizontally holding a stacked substrate formed by bonding a first substrate and a second substrate to each other in order for the first substrate to be located on the second substrate, a chemical liquid to a peripheral portion of the first substrate to move the chemical liquid from the peripheral portion of the first substrate into a gap between the first substrate and the second substrate; and hardening the chemical liquid moved into the gap.
[2] The substrate processing method of [1],
wherein, in the supplying of the chemical liquid to the peripheral portion of the first substrate to move the chemical liquid from the peripheral portion of the first substrate into the gap, the chemical liquid is supplied to the peripheral portion of the first substrate from a first region through which a peripheral portion of the stacked substrate passes while rotating the stacked substrate.
[3] The substrate processing method of [2],
wherein, in the supplying of the chemical liquid to the peripheral portion of the first substrate to move the chemical liquid from the peripheral portion of the first substrate into the gap, the stacked substrate is rotated at a rotational speed allowing a centrifugal force generated by the rotating not to suppress the chemical liquid from being moved into the gap.
[4] The substrate processing method of [2] or [3],
wherein, in the supplying of the chemical liquid to the peripheral portion of the first substrate to move the chemical liquid from the peripheral portion of the first substrate into the gap, the chemical liquid is supplied toward an outer peripheral surface of the first substrate from diagonally above.
[5] The substrate processing method of [2] or [3],
wherein, in the supplying of the chemical liquid to the peripheral portion of the first substrate to move the chemical liquid from the peripheral portion of the first substrate into the gap, the chemical liquid is supplied to an upper surface of the peripheral portion of the first substrate to be moved into the gap from the upper surface through an outer peripheral surface of the first substrate.
[6] The substrate processing method of [5],
wherein, in the supplying of the chemical liquid to the peripheral portion of the first substrate to move the chemical liquid from the peripheral portion of the first substrate into the gap, the chemical liquid is supplied to the upper surface of the peripheral portion of the first substrate from diagonally above in a direction away from a rotation center of the stacked substrate.
[7] The substrate processing method of [5],
wherein, in the supplying of the chemical liquid to the peripheral portion of the first substrate to move the chemical liquid from the peripheral portion of the first substrate into the gap, the chemical liquid is supplied between the upper surface and a guide member in a state where the guide member is positioned to face the upper surface.
[8] The substrate processing method of [5],
wherein, in the supplying of the chemical liquid to the peripheral portion of the first substrate to move the chemical liquid from the peripheral portion of the first substrate into the gap, the chemical liquid is supplied between the outer peripheral surface of the first substrate and a guide member in a state where the guide member is positioned to face the outer peripheral surface.
[9] The substrate processing method of any one of [1] to [8],
wherein, in the hardening of the chemical liquid, the chemical liquid is hardened by a heat treatment.
[10] The substrate processing method of any one of [1] to [9], further including:
performing a hydrophilization processing on a peripheral portion of the stacked substrate before the supplying of the chemical liquid.
[11] The substrate processing method of [2] or [3], further including:
supplying a cleaning liquid to the peripheral portion of the first substrate to remove the chemical liquid remaining on the peripheral portion of the first substrate.
[12] The substrate processing method of [11], further including:
supplying a cleaning liquid to a peripheral portion of the second substrate to remove the chemical liquid remaining on the peripheral portion of the second substrate.
[13] The substrate processing method of [11],
wherein a rotational speed of the stacked substrate in the supplying of the cleaning liquid to the peripheral portion of the first substrate is higher than a rotational speed of the stacked substrate in the supplying of the chemical liquid to the peripheral portion of the first substrate to move the chemical liquid from the peripheral portion of the first substrate into the gap.
[14] The substrate processing method of any one of [1] to [13], further including:
detecting a state of the chemical liquid supplied to the gap; and
adjusting a supply amount of the chemical liquid based on a detection result of the state of the chemical liquid.
[15] The substrate processing method of any one of [1] to [14], further including:
supplying an inert gas toward an outer peripheral surface of the stacked substrate after the supplying of the chemical liquid to the peripheral portion of the first substrate to move the chemical liquid from the peripheral portion of the first substrate into the gap.
[16] The substrate processing method of [2] or [3],
wherein after the supplying of the chemical liquid to the peripheral portion of the first substrate to move the chemical liquid from the peripheral portion of the first substrate into the gap is repeated multiple times, the chemical liquid is hardened.
[17] The substrate processing method of [16], further including:
temporarily increasing a rotational speed of the stacked substrate after the supplying of the chemical liquid to the peripheral portion of the first substrate to move the chemical liquid from the peripheral portion of the first substrate into the gap is performed and before the supplying of the chemical liquid to the peripheral portion of the first substrate to move the chemical liquid from the peripheral portion of the first substrate into the gap is performed next.
[18] The substrate processing method of [17],
wherein after the supplying of the chemical liquid to the peripheral portion of the first substrate to move the chemical liquid from the peripheral portion of the first substrate into the gap and the temporarily increasing of the rotational speed of the stacked substrate are repeated multiple times, the chemical liquid is hardened.
[19] A substrate processing apparatus, including:
a chemical liquid supply configured to supply, while horizontally holding a stacked substrate formed by bonding a first substrate and a second substrate to each other in order for the first substrate to be located on the second substrate, a chemical liquid to a peripheral portion of the first substrate and configured to move the chemical liquid from the peripheral portion of the first substrate into a gap between the first substrate and the second substrate; and
a hardening device configured to harden the chemical liquid moved into the gap.
[20] A computer-readable recording medium having stored thereon a substrate processing program that, in response to execution, causes a substrate processing method of any one of [1] to [18] to be performed on a computer.

According to the present disclosure, there are provided the method and the apparatus capable of easily filling the gap between the substrates with the chemical liquid.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim

1. A substrate processing method, comprising:
supplying, while horizontally holding a stacked substrate formed by bonding a first substrate and a second substrate to each other in order for the first substrate to be located on the second substrate, a chemical liquid to a peripheral portion of the first substrate to move the chemical liquid from the peripheral portion of the first substrate into a gap between the first substrate and the second substrate; and
hardening the chemical liquid moved into the gap.

2. The substrate processing method of claim 1,
wherein, in the supplying of the chemical liquid to the peripheral portion of the first substrate to move the chemical liquid from the peripheral portion of the first substrate into the gap, the chemical liquid is supplied to the peripheral portion of the first substrate from a first region through which a peripheral portion of the stacked substrate passes while rotating the stacked substrate.

3. The substrate processing method of claim 2,
wherein, in the supplying of the chemical liquid to the peripheral portion of the first substrate to move the chemical liquid from the peripheral portion of the first substrate into the gap, the stacked substrate is rotated at a rotational speed allowing a centrifugal force generated by the rotating not to suppress the chemical liquid from being moved into the gap.

4. The substrate processing method of claim 2,
wherein, in the supplying of the chemical liquid to the peripheral portion of the first substrate to move the chemical liquid from the peripheral portion of the first substrate into the gap, the chemical liquid is supplied toward an outer peripheral surface of the first substrate from diagonally above.

5. The substrate processing method of claim 2,
wherein, in the supplying of the chemical liquid to the peripheral portion of the first substrate to move the chemical liquid from the peripheral portion of the first substrate into the gap, the chemical liquid is supplied to an upper surface of the peripheral portion of the first substrate to be moved into the gap from the upper surface through an outer peripheral surface of the first substrate.

6. The substrate processing method of claim 5,
wherein, in the supplying of the chemical liquid to the peripheral portion of the first substrate to move the chemical liquid from the peripheral portion of the first substrate into the gap, the chemical liquid is supplied to the upper surface of the peripheral portion of the first substrate from diagonally above in a direction away from a rotational center of the stacked substrate.

7. The substrate processing method of claim 5,
wherein, in the supplying of the chemical liquid to the peripheral portion of the first substrate to move the chemical liquid from the peripheral portion of the first substrate into the gap, the chemical liquid is supplied between the upper surface and a guide member in a state where the guide member is positioned to face the upper surface.

8. The substrate processing method of claim 5,
wherein, in the supplying of the chemical liquid to the peripheral portion of the first substrate to move the chemical liquid from the peripheral portion of the first substrate into the gap, the chemical liquid is supplied between the outer peripheral surface of the first substrate and a guide member in a state where the guide member is positioned to face the outer peripheral surface.

9. The substrate processing method of claim 1,
wherein the hardening of the chemical liquid is performed by a heat treatment.

10. The substrate processing method of claim 1, further comprising:
performing a hydrophilization processing on a peripheral portion of the stacked substrate before the supplying of the chemical liquid.

11. The substrate processing method of claim 2, further comprising:
supplying a cleaning liquid to the peripheral portion of the first substrate to remove the chemical liquid remaining on the peripheral portion of the first substrate.

12. The substrate processing method of claim 11, further comprising:
supplying a cleaning liquid to a peripheral portion of the second substrate to remove the chemical liquid remaining on the peripheral portion of the second substrate.

13. The substrate processing method of claim 11,
wherein a rotational speed of the stacked substrate in the supplying of the cleaning liquid to the peripheral portion of the first substrate is higher than a rotational speed of the stacked substrate in the supplying of the chemical liquid to the peripheral portion of the first substrate to move the chemical liquid from the peripheral portion of the first substrate into the gap.

14. The substrate processing method of claim 1, further comprising:
detecting a state of the chemical liquid supplied to the gap; and
adjusting a supply amount of the chemical liquid based on a detection result of the state of the chemical liquid.

15. The substrate processing method of claim 1, further comprising:
supplying an inert gas toward an outer peripheral surface of the stacked substrate after the supplying of the chemical liquid to the peripheral portion of the first substrate to move the chemical liquid from the peripheral portion of the first substrate into the gap.

16. The substrate processing method of claim 2,
wherein the supplying of the chemical liquid to the peripheral portion of the first substrate to move the chemical liquid from the peripheral portion of the first substrate into the gap is repeated multiple times to harden the chemical liquid.

17. The substrate processing method of claim 16, further comprising:
temporarily increasing a rotational speed of the stacked substrate after the supplying of the chemical liquid to the peripheral portion of the first substrate to move the chemical liquid from the peripheral portion of the first substrate into the gap is performed and then detecting a state of the chemical liquid supplied to the gap from an image input by a detector.

18. The substrate processing method of claim 17, wherein
the detector determines whether a supply amount of the chemical liquid is required to be adjusted, and
the method further comprises, in response to the detector determining the supply amount of the chemical liquid is required to be adjusted, repeating the supply of the chemical liquid to the peripheral portion of the first substrate and the temporarily increasing of the rotational speed of the stacked substrate.

19. A substrate processing apparatus, comprising:
a holder for holding a stacked substrate formed by bonding a first substrate and a second substrate to each other in order for the first substrate to be located on the second substrate;
a chemical liquid supply configured to supply, while the holder holds the stacked substrate, a chemical liquid to a peripheral portion of the first substrate and the chemical liquid supply being configured to move the chemical liquid from the peripheral portion of the first substrate into a gap between the first substrate and the second substrate; and
a hardening device configured to harden the chemical liquid moved into the gap.

20. A non-transitory computer-readable recording medium having stored thereon a substrate processing program that, in response to execution by a computer, causes a substrate processing method of claim 1 to be performed on the computer.
